(19) United States
(12) Patent Application Publication
(10) Pub. No.: US 2010/0123502 A1
(43) Pub. Date: May 20, 2010

(54) SYSTEM FOR PROVIDING A SUBSTANTIALLY UNIFORM POTENTIAL PROFILE

(76) Inventors: Imran A. Bhutta, Moorestown, NJ (US); Scott D. Ivins, Voorhees, NJ (US)

Correspondence Address: BLANK ROME LLP, WATERGATE, 600 NEW HAMPSHIRE AVENUE, N.W., WASHINGTON, DC, 20037, US

(21) Appl. No.: 12/500,433

(22) Filed: Jul. 9, 2009

Related U.S. Application Data
(60) Provisional application No. 61/134,385, filed on Jul. 9, 2008.
(60) Provisional application No. 61/209,788, filed on Mar. 11, 2009.

(51) Int. Cl. H03K 5/01; H03L 5/00; H03H 11/16; H03H 7/38

(52) U.S. Cl. 327/237; 327/306; 333/32; 327/100

(57) ABSTRACT

A system for providing at least two output signals to produce a substantially uniform potential profile includes a signal generator adapted to emit a frequency at least about 30 megahertz, a splitter in communication with the signal generator, and a signal manipulator in communication with the splitter. The splitter is adapted to split the signal of the signal generator into the two output signals, and the signal manipulator is adapted to manipulate a phase, a gain, or an impedance of the two output signals. The signal manipulator manipulates the two output signals so that the two output signals produce the substantially uniform potential profile.

### CROSS-REFERENCE TO RELATED APPLICATIONS

This application claims priority to provisional patent application Ser. No. 61/134,385, filed Jul. 9, 2008, and provisional patent application Ser. No. 61/209,788, filed Mar. 11, 2009, both of which are incorporated herein by reference in their entirety.

### FIELD OF THE INVENTION

The present invention relates to system for providing a substantially uniform potential profile. In particular, the present invention relates to a system for providing a substantially uniform potential profile that can be used with plasma.

### BACKGROUND OF THE INVENTION

Semiconductor materials are utilized in many different applications. Thus, there is a continued need to fabricate semiconductor material quickly and at reduced cost. The fabrication of semiconductor materials often includes a deposition step and an etching step. Deposition encompasses any process that grows, coats, or otherwise transfers material onto another substance, such as a wafer, and etching includes any process that removes a portion of the transferred material from the other substance. Deposition can be accomplished by use of plasma in chemical vapor deposition, and etching can be completed by plasma asking. Thus, plasma can be used in the processes of deposition and etching.

Plasma is any gas in which a significant percentage of the atoms or molecules are ionized. In deposition, plasma can be used in chemical vapor deposition (CVD) which is a chemical process wherein a substrate or a wafer is exposed to one or more volatile precursors, which react or decompose on a surface of the substrate to produce the desired deposit. CVD processes involving plasma include microwave-assisted plasma CVD, plasma-enhanced CVD, and remote plasma-enhanced CVD. In CVD processes involving plasma, a thin film is deposited on a surface as a portion of the plasma changes phase to a solid on the surface.

The plasma is generally created by a radiofrequency (RF) signal or a direct current discharge between two electrodes. When plasma is created by an RF signal, the RF signal is typically around 13 MHz, however a very high frequency (VHF) RF signal provides a faster deposition process and thus faster manufacturing of semiconductor materials. Unfortunately, a VHF RF signal creates standing waves when the signal is applied to the relatively large electrodes required for photovoltaic cells and large flat panel displays. Standing waves produce non-uniform deposition rates and poor crystalline qualities for plasma-enhanced CVD for depositing amorphous and micro-crystalline silicon.

Thus, there is a need in the art for a system that uses VHF RF signals to manufacture semiconductor material that minimizes the effects of standing waves.

### SUMMARY OF THE INVENTION

Accordingly, the present invention provides a system for providing a substantially uniform potential profile.

An exemplary embodiment of the invention provides a system for providing at least two output signals to produce a substantially uniform potential profile. The system includes a signal generator adapted to emit a frequency at least about 30 megahertz, a splitter in communication with the signal generator, and a signal manipulator in communication with the splitter. The splitter is adapted to split the signal of the signal generator into the two output signals, and the signal manipulator is adapted to manipulate a phase, a gain, or an impedance of the two output signals. The signal manipulator manipulates the two output signals so that the two output signals produce the substantially uniform potential profile.

Another exemplary embodiment of the invention provides a system for providing at least two output signals to produce a substantially uniform potential profile. The system includes a phase adjuster, signal generators in communication with the phase adjuster, and an impedance matcher to substantially match an input impedance of a load in communication with the system. The signal generators are adapted to emit a signal with a frequency at least about 30 megahertz with a phase controlled by the phase adjuster. The phase adjuster manipulates the two output signals so that the at least two output signals produce the substantially uniform potential profile.

Yet another exemplary embodiment of the invention provides a system for providing at least two signals to produce a substantially uniform potential profile. The system includes a first signal generator adapted to emit a first signal with a first phase shift, a second signal generator adapted to emit a second signal with a second phase shift, and a controller in communication with the first signal generator and the second signal generator. The second signal generator is in communication with the first signal generator. The controller is adapted to incrementally change the first phase shift and the second phase shift at a predetermined time increment. At least one of the first phase shift and the second phase shift is adjusted to produce the substantially uniform potential profile.

Other objects, advantages and salient features of the invention will become apparent from the following detailed description, which, taken in conjunction with the annexed drawings, discloses a preferred embodiment of the present invention.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a normalized potential profile at about 13.56 MHz for a center-fed 100 cm×100 cm source;

FIG. 2 is a normalized potential profile at about 81.36 MHz for a center-fed 100 cm×100 cm source;

FIG. 3 is a schematic of a system for providing a substantially uniform potential profile according to an embodiment of the invention;

FIG. 4 is a normalized potential profile at about 81.36 MHz for a multi-fed 100 cm×100 cm source;

FIG. 5 is a schematic of a system for providing a substantially uniform potential profile according to another embodiment of the invention;

FIG. 6 is a schematic of a system for providing a substantially uniform potential profile according to yet another embodiment of the invention;

FIG. 7 is a schematic of signal generators according to a fourth embodiment of the invention;

FIG. 8 is a schematic of the output of two signal generators according to a fifth embodiment of the invention;

FIG. 9 is a chart of the phase relationship of signals of the signal generators shown in FIG. 8;

FIG. 10 is a schematic of the output of four signal generators according to a sixth embodiment of the invention;

FIG. 11 is a chart of the phase relationship of signals of the signal generators shown in FIG. 10;

FIG. 12 is a schematic of the output of five signal generators according to a seventh embodiment of the invention;

FIG. 13 is a chart of the phase relationship of signals of the signal generators shown in FIG. 12; and

FIG. 14 is a schematic of a system with a controller according to an eight embodiment of the invention.

### DETAILED DESCRIPTION OF THE INVENTION

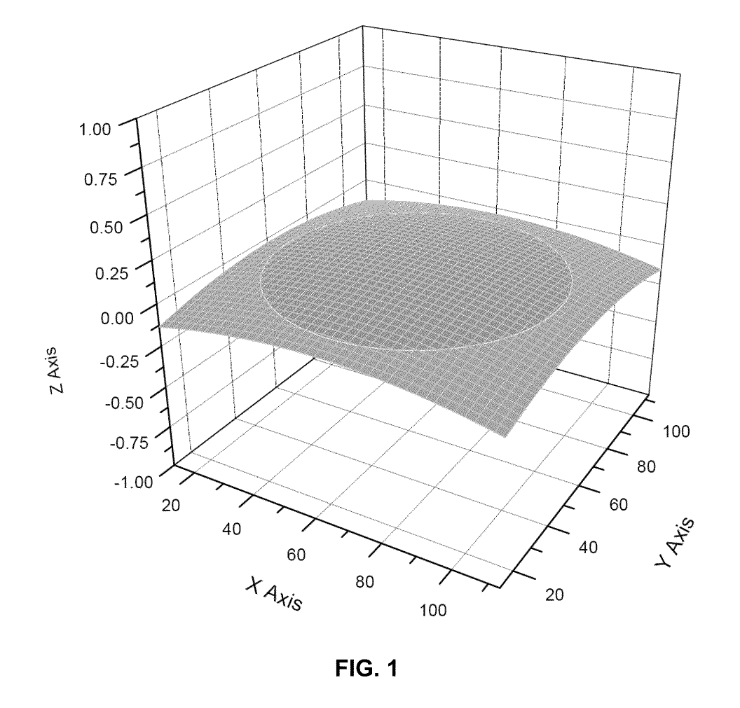

Referring to FIGS. 1-14, the invention relates to providing a substantially uniform potential profile. Such a substantially uniform potential profile can be applied to a plasma that, for example, is used in the manufacture of semiconductor material. The invention allows the use of very high frequency (VHF) plasma. VHF plasma can be used for semiconductor etching and deposition processes. Using VHF plasma provides deposition rates for materials, such as, amorphous silicon (a:Si), nanocrystalline silicon (nc-Si), and microcrystalline silicon (uc-Si) that are approximately seven to eight times greater than deposition rates using plasma at about 13.56 Mhz. However, VHF plasma develops a non-uniformity over a large surface area, and the non-uniformity of VHF plasma limits its use in semiconductor material fabrication. The invention can minimize the non-uniformity of VHF plasma.

Referring to FIG. 1, a normalized potential profile at about 13.56 MHz for a center-fed 100 cm×100 cm source is shown. Along the z-axis of the figure, the potential value of the profile has been normalized to zero, and the area that the potential profile covers is plotted along the x and y axes. As shown in the figure, the potential profile at about 13.56 MHz is relatively uniform. That is, the potential profile has a potential value very close to zero (as indicated on the z-axis) over the entire area defined by the x and y axes. However, as the frequency increases, the potential profile becomes less uniform.

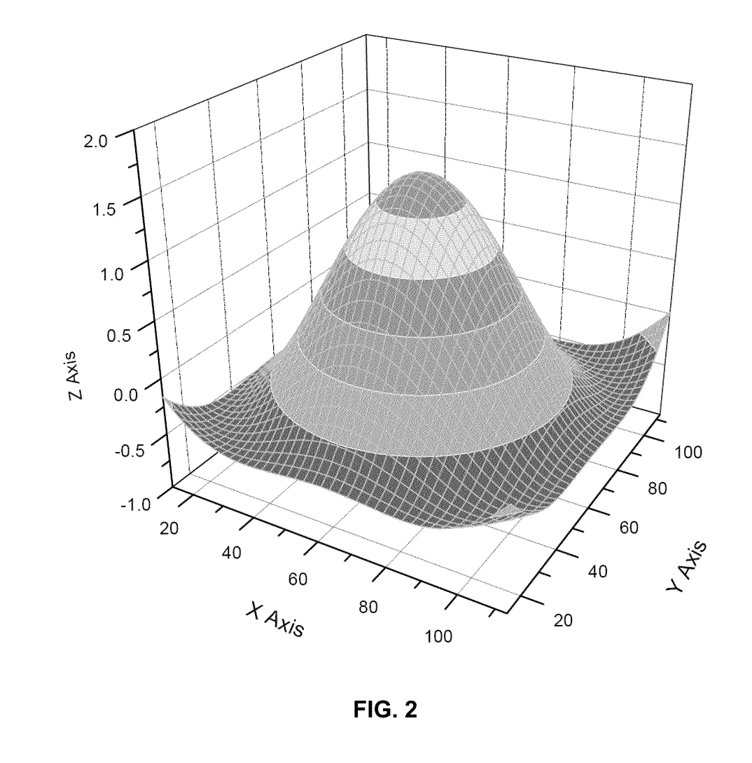

Referring to FIG. 2, a normalized potential profile at about 81.36 MHz for a center-fed 100 cm×100 cm source is shown. Similar to FIG. 1, the potential value normalized to zero is plotted along the z-axis, and the area that the potential profile covers is plotted along the x and y axes. Comparing FIG. 2 and FIG. 1, as the frequency enters the very high frequency range, approximately 30 Mhz to approximately 300 MHz, the potential profile becomes increasingly non-uniform. As shown in the figure, the potential profile has a shape with a prominent protuberance in its approximate center. Following the potential profile from the edge of the area to the approximate center of the area covered by the profile (located at approximately 50 on the x axis and at approximately 50 on the y axis), the normalized potential value rises from approximately zero to approximately 1.0 to 1.5. Thus, to utilize VHF plasma, the non-uniformity of the applied potential must be minimized.

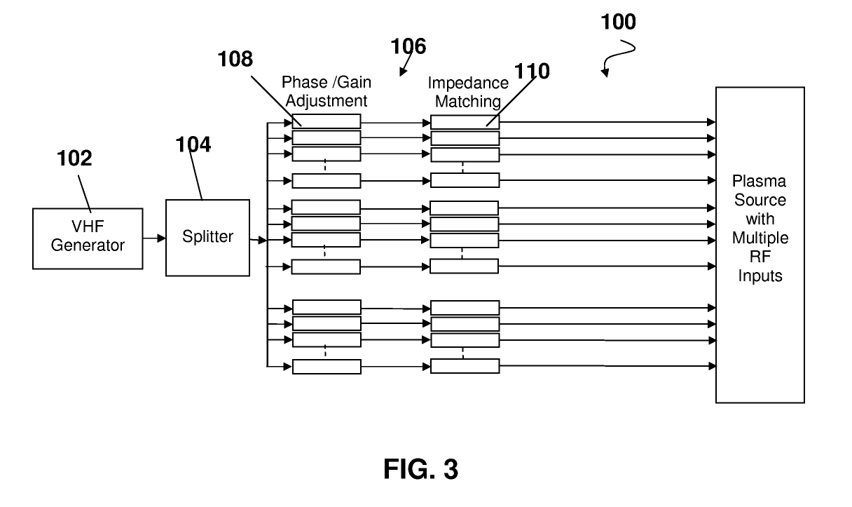

Referring to FIG. 3, a schematic of a system 100 according to one embodiment of the invention is shown. The system 100 includes at least a signal generator 102, a splitter 104 in communication with the signal generator 102, and a signal manipulator 106 in communication with the splitter 104.

The signal generator 102 provides a repeating or non-repeating signal for the system 100. The signal generator 102 can be an electronic signal generator in either the digital or analog domain, a function generator, an arbitrary waveform generator, a tone signal generator, an audio signal generator, a video signal generator, a radiofrequency signal generator, a combination of the aforementioned, or some other component that provides a signal. In the embodiment shown in FIG. 3, the signal generator 102 is a VHF signal generator that provides a VHF radiofrequency (RF) signal for use in the system 100. Although only a single signal generator 102 is shown, there can be more than one signal generator 102. The single signal generator 102 shown is exemplary only and not meant to be limiting. The optimal number of signal generators 102 may be more than the one shown. The exact number of signal generators 102 depends on, for example, the configuration of the system 100 or the requirements of any components in communication with the system 100.

The splitter 104 is in communication with the signal generator 102 and transforms the output of the signal generator 102 into two or more signals based on the signal from the signal generator 102. The two or more signals then become outputs from the splitter 104. The splitter 104 can be an analog or digital filter, a hybrid coil, a bridge transformer, a combination of the aforementioned, or some other component that can transform an input signal into two or more output signals. Although only a single splitter 104 is shown, the single splitter 104 shown is exemplary only and not meant to be limiting. The optimal number of splitter 104 may be more than the single one shown. The exact number of signal generators 102 depends on, for example, the configuration of the system 100, the number of signal generators 102, or the requirements of any components in communication with the system 100.

The signal manipulator 106 is in communication with the splitter 104 and manipulates the signal from the splitter 104. The signal manipulator 106 can be a phase adjuster, a gain adjuster, an impedance matcher, a frequency manipulator, a combination of the aforementioned, or some other component that can manipulate a signal. The signal manipulator 106 can also include a signal transformer that can transform a signal of one kind into a signal of another kind. For example, the signal transformer can transform an audio signal, video signal, an optic signal, or some other signal into a radiofrequency signal that can be used by the system 100. Furthermore, the signal manipulator 106 can include components to transmit the signal from the splitter 104 to a component in communication with the system 100. The signal manipulator 106 can include one or more wires, a wireless transmitter, a wireless receiver, one or more coaxial cables, a microstrip, combinations of the aforementioned, or some other component or components able to transmit or communicate a signal. Similar to the other components of the system 100, the number of signal manipulators 106 shown is exemplary only and not meant to be limiting. The optimal number of signal manipulators 106 may be more or less than the twelve signal manipulators 106 shown. The exact number of signal manipulators 106 depends on, for example, the configuration of the system 100, the number of splitters 104, or the requirements of any components in communication with the system 100.

In the embodiment shown in FIG. 3, the system 100 is in communication with a plasma source with multiple RF inputs. Also, the depicted system 100 includes a single VHF RF generator as the signal generator 102. The VHF RF generator provides RF power to the system 100 shown, and the splitter 104 transforms the RF power into multiple RF outputs at the output of the splitter 104, In the system 100 shown, the splitter 104 provides twelve RF outputs, and the RF outputs are transmitted to the signal manipulator 106. The signal manipulator 106 of the depicted embodiment includes a combined phase and gain adjuster 108, an impedance matcher 110, and other components, such as coaxial cables or microstrips, to communicate the signal from the splitter 104 to the plasma source with multiple RF inputs. The phase and gain adjuster 108 has phase/gain adjustment circuitry, and the impedance matcher 110 includes impedance matching circuitry to transform the input impedance of the plasma chamber for maximum power transfer.

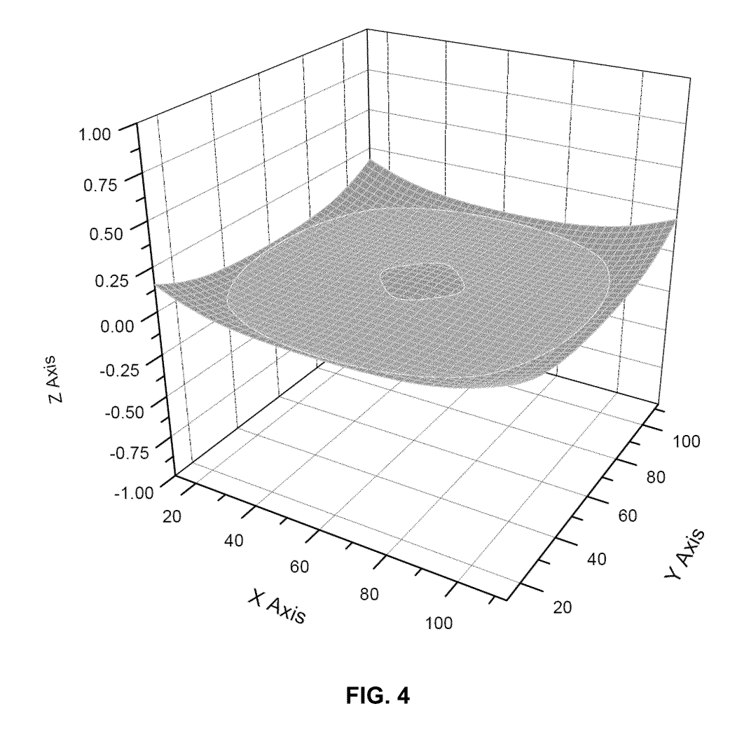

Referring to FIG. 4, a normalized potential profile at about 81.36 MHz for a multi-fed 100 cm×100 cm source is shown. The system 100 shown in FIG. 3 adjusts the phase and amplitude of the RF signals from the splitter 102 such that the potential profile on the plasma source is substantially uniform as shown in FIG. 4. The normalized potential profile shown is for a multi-feed plasma source with phase and amplitude adjustment, such as the one shown in FIG. 3.

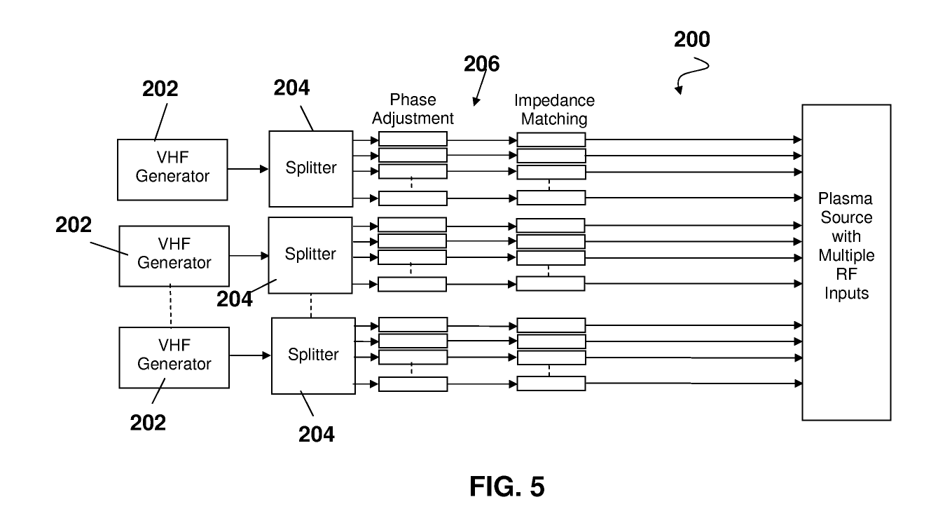

Referring to FIG. 5, a schematic of a system 200 according to another embodiment of the invention is shown. Similar to system 100, the system 200 includes at least a signal generator 202, a splitter 204 in communication with the signal generator 202, and a signal manipulator 206 in communication with the splitter 204. However, the system 200 has more than one signal generator 202, and a splitter 204 in communication with each signal generator 202.

The several signal generators 202 can be operated at different output power levels. The signal generators 202 may have a single common input or output. Alternatively, one of the signal generators 202 may act as a source for a master signal that is transmitted to the other signal generators 202 so that the other signal generators 202 can operate at substantially the same signal. With the differences noted above, the signal generators 202 are otherwise substantially similar to the signal generator 102. Thus, a further detailed description of the signal generators 202 is omitted.

The splitters 204 and the signal manipulators 206 are substantially similar to the splitter 104 and signal manipulator 106, respectively, of system 100. Thus, detailed descriptions of the splitters 204 and the signal manipulator 206 are omitted.

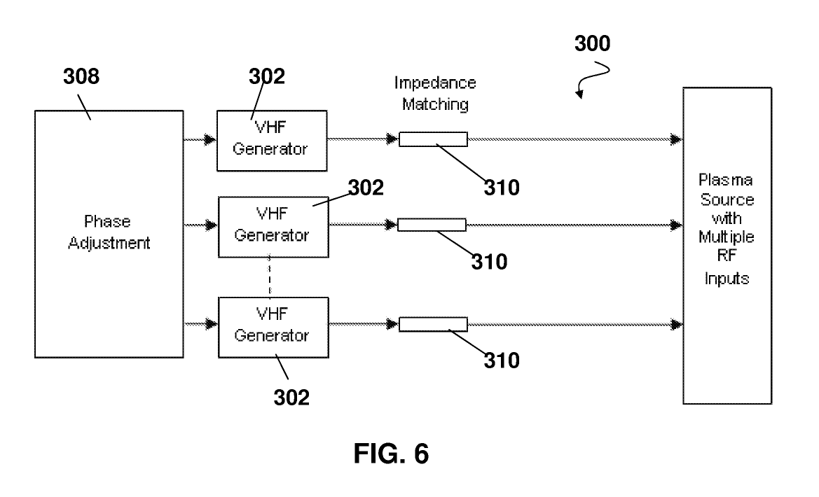

Referring to FIG. 6, a schematic of a system 300 according to yet another embodiment of the invention is shown. The system 300 includes at least a signal generator 302 that is in communication with a phase adjuster 308, and an impedance matcher 310 that is in communication with the signal generator 302. When compared to the system 100, the phase adjuster 308 is upstream of the signal generator 302.

The system 300 shown in FIG. 6 is in communication with a plasma source with multiple RF inputs. Also, the depicted system 300 includes more than one VHF RF generator as the signal generator 302. The several VHF RF generators provide RF power to the system 300 shown. Each of the VHF RF generator is able to operate at different power levels and at different phase relationships when compared to the other VHF RF generators in system 300. Each output from the VHF RF generators is then transmitted to the plasma chamber through RF connections, such as coaxial cables and microstrips, and an impedance matcher 310 that includes impedance matching circuitry, to transform the input impedance of the plasma chamber for maximum power transfer.

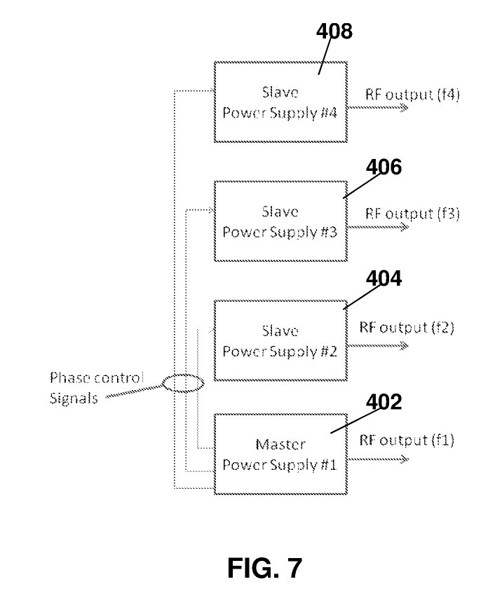

Referring to FIG. 7, a schematic of signal generators 402, 404, 406, and 408 is shown. In the embodiment shown, the signal generators 402 are VHF RF signal generators, but the invention is not limited to VHF RF signal generators. One of the signal generators 402 provides output phase information to the other signal generators 404, 406, and 408. Thus, signal generator 402 can be designated the master, and the other signal generators 404, 406, and 408 can be designated slave. The phase information can be machine code, low level RF (also known as common exciter oscillator or CEX), a combination of the two, or some other component or signal that transmits phase information between signal generators 402, 404, 406, and 408. The master signal generator 402 can coordinate the phase control of the other signal generators 404, 406, and 408 so that their respective outputs have substantially the same or different phases. Although four signal generators 402, 404, 406, and 408 are shown, the number of signal generators 402, 404, 406, and 408 shown is exemplary only and not meant to be limiting. The optimal number of signal generators 402, 404, 406, and 408 may be more or less than the four shown. The exact number of signal generators 402, 404, 406, and 408 depends on, for example, the configuration of the system 100, the number of outputs required, or the requirements of any components that receive the signal from the signal generators 402, 404, 406, and 408. Furthermore, a single signal generator with multiple outputs may be used instead of the signal generators 402, 404, 406, and 408.

In the embodiment shown, the master signal generator 402 is substantially similar to the slave signal generators 404, 406, and 408. However, the master signal generator 402 can adjust, for example, the phase shift from approximately 0° to approximately 360°, the incremental change in the phase from approximately 0.01° to approximately 360°, and the time period between incremental changes in the phase from approximately 1 microsecond to approximately 100 minutes. The slave signal generators 404, 406, and 408 substantially follow the master signal generator 402. Each of the slave signal generators 404, 406, and 408 can have their own independent control loop and power measurement.

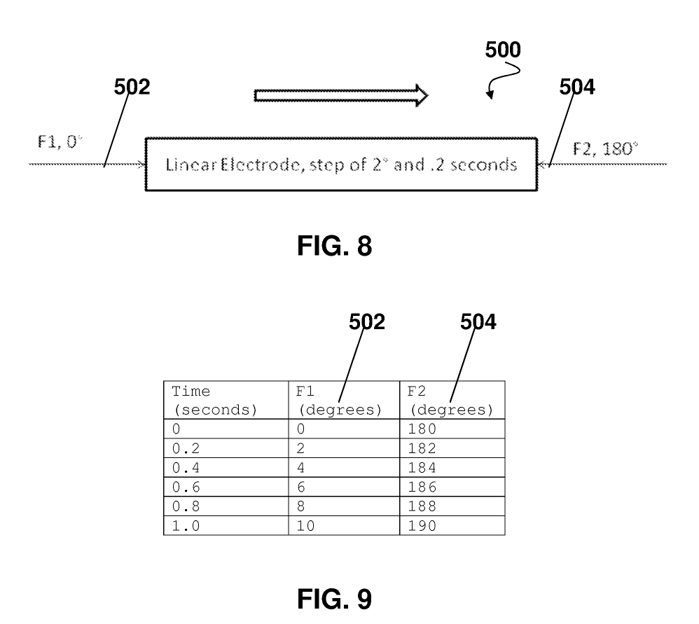

Referring to FIG. 8, a schematic of a system 500 with two signal generators that provide signals 502 and 504. The figure shows an example of a two RF output system 500 with two signal generators, such as a master and a slave, that provide signals 502 and 504, respectively. The signals 502 and 504 can be transmitted to, for example, electrodes used for plasma-enhanced chemical vapor deposition (CVD). The system 500 can include two discrete signal generators or a single signal generator with two outputs. The signals 502 and 504 begin with different phases but are incremented by substantially the same amount at substantially the same time. In particular, one signal 502 starts at about 0°, and the other signal starts at about 360°. Then, after approximately 0.2 seconds of time has elapsed, each signal 502, 504 increments by about +2°. Thus, as shown in FIG. 9, at time 0, one signal 502 is at 0°, and the other signal 504 is at 180°. At time 0.2 seconds, one signal 502 is at 2°, and the other signal 504 is at 182°. At time 0.4 seconds, signal 502 increases to 4°, and signal 504 increases to 184°. Thus, each time that 0.2 seconds elapses, each signal 502, 504 increases by 2°. Therefore, at time 1.0 second, signal 502 has increased to 10°, and signal 504 has increased to 190°.

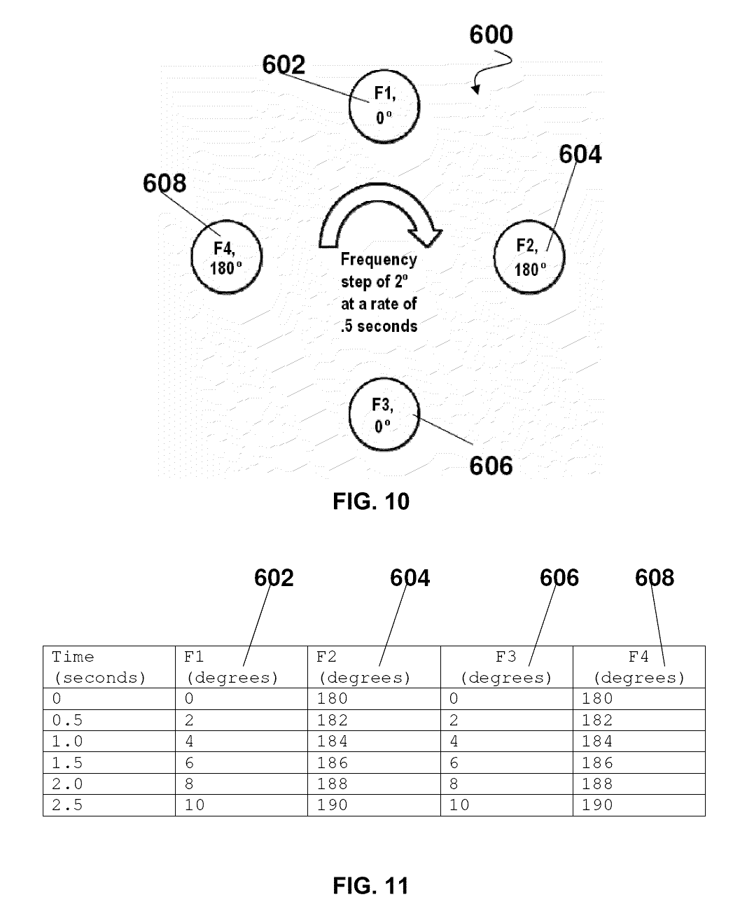

Referring to FIG. 10, a schematic of the output from four signal generators is shown. The figure shows an example of a four RF output system 600 with four signals 602, 604, 606, and 608. The signals 602, 604, 606, and 608 can be from four discrete signal generators or from a single signal generator with four outputs. The signals 602, 604, 606, and 608 can be transmitted to, for example, electrodes used for plasma-enhanced CVD. The signals 602, 604, 606, and 608 begin with different phases but are incremented by generally the same amount at generally the same time. Specifically, in the embodiment shown, the signals 602, 604, 606, and 608 are placed to substantially form a ring, with signal 602 at the top of the ring in the figure. The other depicted signals are arranged clockwise from signal 602. The signal 602 at the top of the ring and the signal 606 at the bottom of the ring begin at 0°, while the signals 604 and 608 at the sides of the ring begin at 180°. The terms “top,” “bottom,” and “sides” are not meant to be limiting, but rather to describe the positional relationship between the signals 602, 604, 606, and 608 with respect to each other. Then, after 0.5 second of time has elapsed, each signal 602, 604, 606, and 608 increments by +2°. Thus, as shown in FIG. 11, at time 0, signal 602 is at 0°, signal 604 is at 180°, signal 606 is at 0°, and signal 608 is at 180°. At time 0.5 second, signal 602 is at 2°, signal 604 is at 182°, signal 606 is at 2°, and signal 608 is at 182°. At time 1.0 second, signal 602 is at 4°, signal 604 is at 184°, signal 606 is at 4°, and signal 608 is at 184°. Thus, each time that 0.5 second elapses, each signal 602, 604, 606, and 608 increases by 2°. Therefore, at time 2.5 seconds, signal 602 is at 10°, signal 604 is at 190°, signal 606 is at 10°, and signal 608 is at 190°.

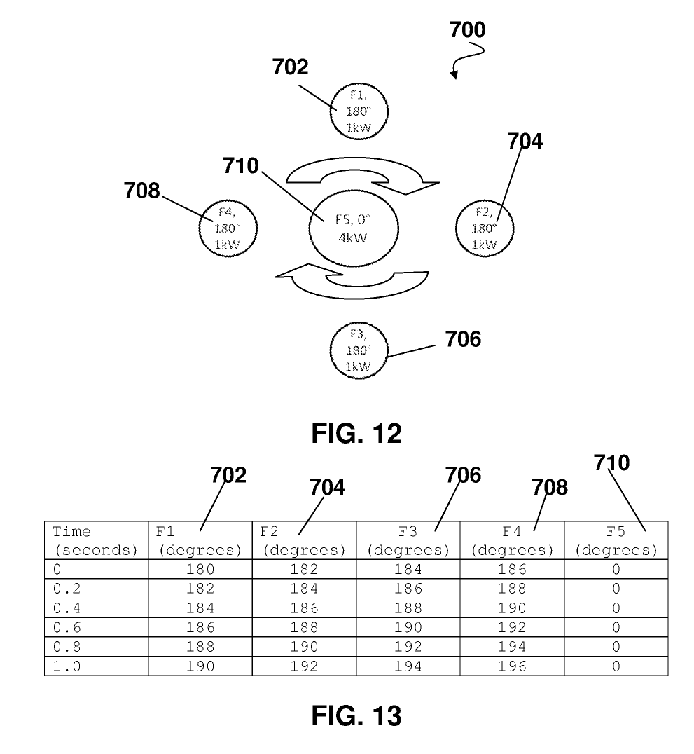

Referring to FIG. 12, a schematic of the output from five signal generators according to another embodiment is shown. Unlike system 600 shown in FIG. 10, the system 700 includes signal generators that are at different power levels. The signal generators provide signals 702, 704, 706, 708, and 710. The signals 702, 704, 706, 708, and 710 can be from five discrete signal generators or from a single signal generator with five outputs. The signals 702, 704, 706, 708, and 710 can then be transmitted to, for example, electrodes used for plasma-enhanced CVD. As shown in the figure, the signals 702, 704, 706, 708, and 710 are arranged in a ring with signal 710 at the center. Signal 702 is at the top of the ring, and the other signals 704, 706, and 708 are arranged clockwise from signal 702. The signals 702, 704, 706, 708, and 710 begin with different phases but are incremented by substantially the same amount at substantially the same time. Also, in the depicted embodiment, signals 702, 704, 706, and 708 are at 1 kW, while the center signal is at 4 kW. Furthermore, the system 700 can sense the phase of each of the signals 702, 704, 706, 708, and 710 to provide real time feedback for better precision and repeatability.

As shown in FIG. 13, at time 0, signal 702 is at 180°, signal 704 is at 182°, signal 706 is at 184°, signal 708 is at 186°, and the center signal 710 is at 0°. After 0.2 seconds of time has elapsed, each signal increments by +2° except for the center signal 710. Thus, at time 0.2 second, signal 702 is at 182°, signal 704 is at 184°, signal 706 is at 186°, signal 708 is at 188°, while the center signal 710 remains at 0°. Then, at time 0.4 second, signal 702 is at 184°, signal 704 is at 186°, signal 706 is at 188°, signal 708 is at 190°, while the center signal 710 remains at 0°. The process continues so that at time 1.0 second, signal 702 is at 190°, signal 704 is at 192°, signal 706 is at 194°, signal 708 is at 196°, and the center signal 710 is at 0°.

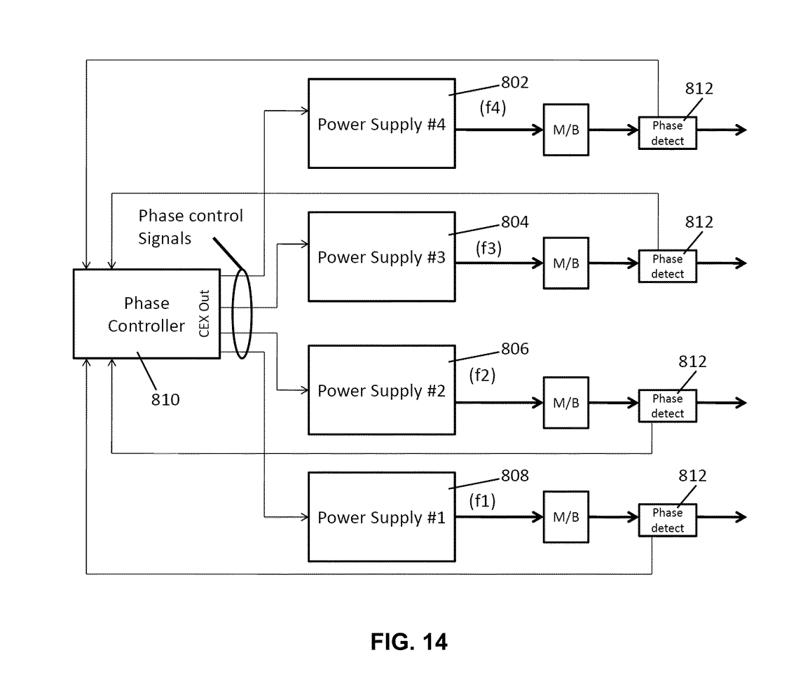

Referring to FIG. 14, a schematic of a system 800 with a single controller 810 is shown. In the depicted embodiment, the controller 810 controls all the signal generators 802, 804, 806, and 808 of the system 800. Each signal generator 802, 804, 806, and 808 is substantially slaved to the controller 810. Thus, when the controller 810 is a phase controller as shown in the figure, the controller 810 can send phase information to each signal generator 802, 804, 806, and 808 to control the phase relationship between the signal generators 802, 804, 806, and 808. Also, as shown in the figure, the system 800 can include one or more phase detectors 812 that can provide feedback information to the controller 810.

While a particular embodiment has been chosen to illustrate the invention, it will be understood by those skilled in the art that various changes and modifications can be made therein without departing from the scope of the invention as defined in the appended claims.

What is claimed is:

1. A system for providing at least two output signals to produce a substantially uniform potential profile, the system comprising:
a signal generator, the signal generator adapted to emit a signal with a frequency at least about 30 megahertz;
a splitter in communication with the signal generator, the splitter adapted to split the signal into the at least two output signals; and
a signal manipulator in communication with the splitter, the signal manipulator adapted to manipulate a phase, a gain, or an impedance of the at least two output signals,
wherein the signal manipulator manipulates the at least two output signals so that the at least two output signals produce the substantially uniform potential profile.

2. A system according to claim 1, wherein the signal generator includes a radio frequency signal generator.

3. A system according to claim 1, wherein the signal generator is a plurality of signal generators.

4. A system according to claim 3, wherein each of the plurality of signal generators is in communication with a corresponding splitter.

5. A system according to claim 1, wherein the signal manipulator is a plurality of signal manipulators.

6. A system according to claim 1, wherein the signal manipulator comprises:
a phase adjuster;
a gain adjuster; and
an impedance matcher.

7. A system according to claim 1, wherein the signal manipulator substantially matches the impedance of the at least two output signals to an impedance of a load.

8. A system according to claim 1, wherein the at least two output signals are in communication with a plasma source.

9. A system according to claim 8, wherein the at least two output signals produce the substantially uniform potential profile in a plasma from the plasma source to provide a substantially uniform depositing of a material on a substrate with the substantially uniform potential profile and the plasma.

10. A system for providing at least two output signals to produce a substantially uniform potential profile, the system comprising:
a phase adjuster;
a plurality of signal generators in communication with the phase adjuster, each of the plurality of signal generators adapted to emit a signal with a frequency at least about 30 megahertz with a phase controlled by the phase adjuster; and
an impedance matcher to substantially match an input impedance of a load in communication with the system;
wherein the phase adjuster manipulates the at least two output signals so that the at least two output signals produce the substantially uniform potential profile.

11. A system according to claim 10, wherein the signal generator includes a radio frequency signal generator.

12. A system according to claim 10, wherein the at least two output signals are in communication with a plasma source.

13. A system according to claim 12, wherein the at least two output signals produce the substantially uniform potential profile in a plasma from the plasma source to provide a substantially uniform depositing of a material on a substrate with the substantially uniform potential profile and the plasma.

14. A system for providing at least two signals to produce a substantially uniform potential profile, the system comprising:
a first signal generator adapted to emit a first signal with a first phase shift;
a second signal generator in communication with the first signal generator, the second signal generator adapted to emit a second signal with a second phase shift; and
a controller in communication with the first signal generator and the second signal generator, the controller adapted to incrementally change the first phase shift and the second phase shift at a predetermined time increment,
wherein at least one of the first phase shift and the second phase shift is adjusted to produce the substantially uniform potential profile.

15. A system according to claim 14, wherein the first signal generator includes the controller.

16. A system according to claim 14, wherein the first signal generator includes the second signal generator.

17. A system according to claim 14, wherein the second signal generator is a plurality of second signal generators.

18. A system according to claim 14, wherein the first and second signal generators each include a radio frequency signal generator.

19. A system according to claim 14, wherein the first signal and the second signal are in communication with a plasma source.

20. A system according to claim 19, wherein the first signal and the second signal produce the substantially uniform potential profile in a plasma from the plasma source to provide a substantially uniform depositing of a material on a substrate with the substantially uniform potential profile and the plasma.
